(19) United States
(12) Patent Application Publication
(10) Pub. No.: US 2005/0139913 A1
(43) Pub. Date: Jun. 30, 2005

(54) Method for manufacturing a power device with insulated gate and trench-gate structure having controlled channel length and corresponding device

(76) Inventors: Antonino Sebastiano Alessandria, Catania (IT); Leonardo Fragapane, Catania (IT)

Correspondence Address: HOGAN & HARTSON LLP, ONE TABOR CENTER, SUITE 1500, 1200 SEVENTEENTH ST, DENVER, CO, 80202, US

(21) Appl. No.: 10/996,131

(22) Filed: Nov. 23, 2004

(30) Foreign Application Priority Data
Nov. 28, 2003 (EP) 03425765.9

(51) Int. Cl. H01L 29/94

(52) U.S. Cl. 257/341

(57) ABSTRACT

A method for manufacturing a semiconductor power device with an insulated gate and trench-gate structure integrated on a semiconductor substrate includes providing a body region in the semiconductor substrate, forming a surface source region on the body region, etching the semiconductor substrate and forming a trench to form the trench-gate structure. The method also includes forming a deep portion of the source region along the trench.

### FIELD OF APPLICATION

The present invention relates to a method for manufacturing a power device with an insulated gate and a trench-gate structure having controlled channel length and a corresponding device.

### BACKGROUND OF THE INVENTION

As is known in the art, power devices of the IGBT type (“Insulated Gate Bipolar Transistor”) are used in circuits requiring high voltage and current with a moderate switching frequency, such as motor control circuitry or the like.

The performance of an IGBT device combines the advantages of a bipolar transistor (high conductivity) and those of a field-effect MOS transistor (control voltage with high input resistance), wherein the MOS transistor drives the base current of the bipolar transistor.

These IGBT devices can be generally manufactured in two versions: a first one called “planar gate” and another one called “trench-gate”, whose cross-section can be seen in FIG. 1.

The structure of a “trench-gate” IGBT device includes a substrate 1 of a P+ type semiconductor material whereon an epitaxial layer is grown, split into buffer layer 2 and drift layer 3, of the N+ and N-type respectively. Two differently-doped P regions are formed on drift layer 3: a body region 4 and a deep body region 5. An N-type source region 6 is formed in the body region 4.

Although FIG. 1 relates to an IGBT device, a Power MOS device could be illustrated by removing substrate layer 1.

The IGBT device of FIG. 1 includes a trench-gate structure 7a forming the gate region of the IGBT device and includes a trench made in the semiconductor substrate 1 filled in with a polysilicon layer 7. The trench-gate structure 7a is separated from the other portions of the IGBT device by a silicon oxide coating layer 8 grown on the trench walls. A deposit of a dielectric layer 9, a metal contact 10 on the device front, and a metal contact 11 on the back of the semiconductor substrate 1 complete the device.

In particular, layers 1 and 3 are the conduction electrodes of the bipolar transistor in the IGBT device, while the MOS transistor of the IGBT device includes source 6, drift layer 3, and the trench-gate structure 7a.

In power IGBT devices of the trench-gate type a channel region is formed along the vertical walls of the trench made in the semiconductor substrate 1. Therefore, in such a device, the channel length is given by the difference between the source-body junction depth and the body-drift layer depth.

In particular, the conduction channel region is formed at the interface between the silicon oxide coating layer 8 and the semiconductor layer 3, along the trench walls, in the body region 4.

The main advantages of a trench-gate power IGBT device manufactured with planar technology are: the J-FET resistance is removed with a subsequent decrease in conduction losses; and the possibility of considerably increasing the device integration scale, with a subsequent increase in the current density.

On the other hand, the structure has some drawbacks. In particular, a first drawback is linked to the upper edge of the trench-gate structure 7a, which causes the formation of a beak during the growth of the gate oxide coating layer 8. This unevenness causes a thickening of the electric field, due to the well known peak effect, with a subsequent worsening of the gate oxide break-down voltage.

A second drawback is linked to the considerable increase in the gate oxide area, for the same device active area, even in areas wherein no channel is formed, such as the portion 12 of the gate oxide layer 8 in FIG. 1. This involves an increase in the stray capacitance linked to the device gate terminal.

A first prior art solution to solve the first drawback is to round the upper edge of the trench-gate structure 7a at the interface with the semiconductor substrate 1 surface, as shown in FIG. 2, when etching the semiconductor substrate 1 to avoid the formation of the beak during the growth thereof.

A trench having a substantially countersunk profile is thus obtained. Nevertheless, this solution is technologically quite complex.

A second prior art solution to solve the problem linked to the upper edge of the trench-gate structure 7a is to use a recessed polysilicon structure (etchback of the polysilicon protruding from the trench) in order to confine the polysilicon layer filling within the trench. Therefore, the edge at the upper end of the trench-gate structure 7a is spaced from the device active part.

All this is shown in detail in FIG. 3, wherein the comparison with FIG. 1 clearly shows the effect of the polysilicon etchback even under the edge level of the trench-gate structure 7a, resulting in a concave surface 13.

Nevertheless, this approach involves technical complications due, for example, to the etchback step of the polysilicon layer 7 which must have a controlled overetch step since the depth must be lower than the source junction depth.

It is also known to try and solve the problem linked to the considerable increase of the gate oxide area introducing, on the trench bottom under the gate region, a thick oxide layer 14 called thick-oxide (gate oxide+deposited dielectric), as shown in FIG. 3. This thick oxide layer 14 often fills in the trench bottom up to reach the body region 4 level.

This solution improves both the device break-down (the oxide serves as field-ring) and the gate oxide break-down since the wall portion, wherein a variation of the silicon crystallographic orientation occurs, is excluded from the thin oxide area, and the stray capacitance linked to the gate terminal.

Nevertheless, this approach involves considerable complications due, for example, to the trench filling with an oxide layer of the LTO (Low Temperature Oxide) type.

Moreover, since in a trench-gate IGBT power device the conduction loss component linked to the JFET resistance is almost completely removed, the channel resistance, being strictly dependent on the channel length, becomes one of the main components of conduction losses.

In particular, in the structure formed through polysilicon etchback, shown in FIG. 3, the body-source junction depth is a very important parameter to limit conduction losses.

In fact, for correct device operation, the source region 6 must be deeper than the level to which the polysilicon layer is recessed, therefore the thermal budget attributed to the dopant implanted in the substrate 1 to form the source region must be carefully controlled and is highly dependent on the type of dopant being used.

What is desired, therefore, is to provide a method for controlling the channel length in a insulated trench-gate MOS power device, having such structural and functional features as to allow the channel length to be determined independently from the thermal budget and from the variety of dopant used to form the source region, thus overcoming the limits and drawbacks still affecting prior art devices.

### SUMMARY OF THE INVENTION

According to an embodiment of the present invention a dopant is implanted on the side walls of the trench-gate structure in order to extend the source region on the side walls of the trench-gate structure to a desired depth.

More specifically, an embodiment of present invention relates to a method for manufacturing an insulated trench-gate power device integrated on a semiconductor substrate, including: providing a body region in the semiconductor substrate; providing a surface source region on the body region; etching the semiconductor substrate and forming a trench to realise the trench-gate structure.

According to an embodiment of the present invention an insulated trench-gate power semiconductor device includes: a semiconductor substrate; a body region formed in the semiconductor substrate; a surface source region formed on the body region; and a trench-gate structure effective to form a gate region of the device including a trench made in the semiconductor substrate.

The invention particularly relates, but not exclusively, to a method for controlling the channel length in a power device of the IGBT type (Insulated Gate Bipolar Transistor) and the following description is made with reference to this field of application for convenience of illustration only.

The features and advantages of the method and device according to the invention will be apparent from the following description of embodiments thereof given by way of non-limiting example with reference to the attached drawings.

### BRIEF DESCRIPTION OF THE DRAWINGS

In the drawings:

FIG. 1 is a cross-sectional schematic view of a power device of the trench-gate type realised according to the prior art;

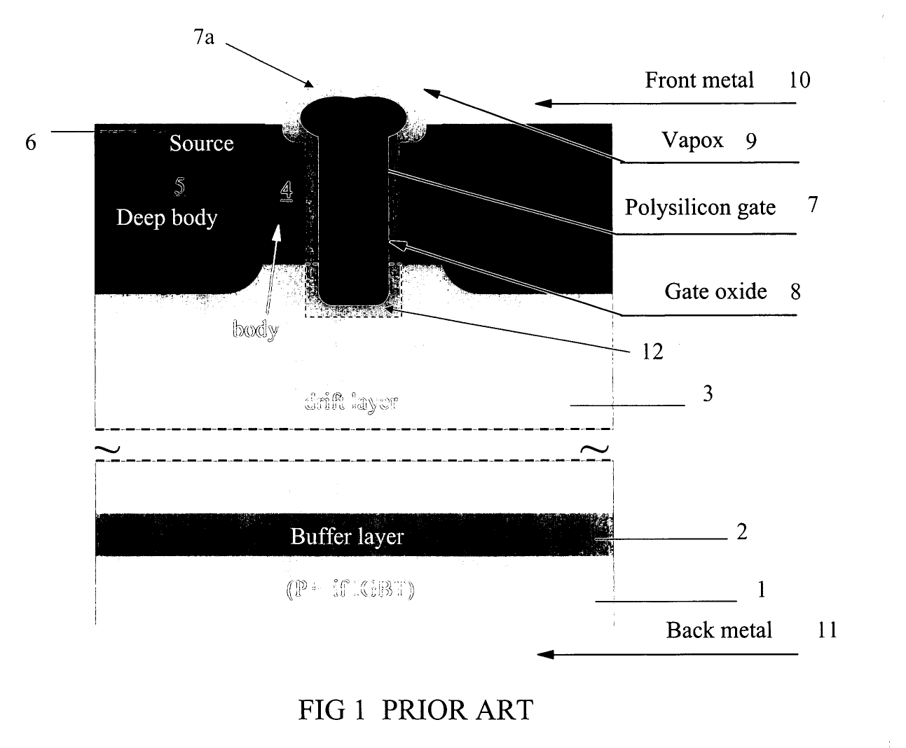

FIG. 2 schematically shows a first alternative of the device of FIG. 1;

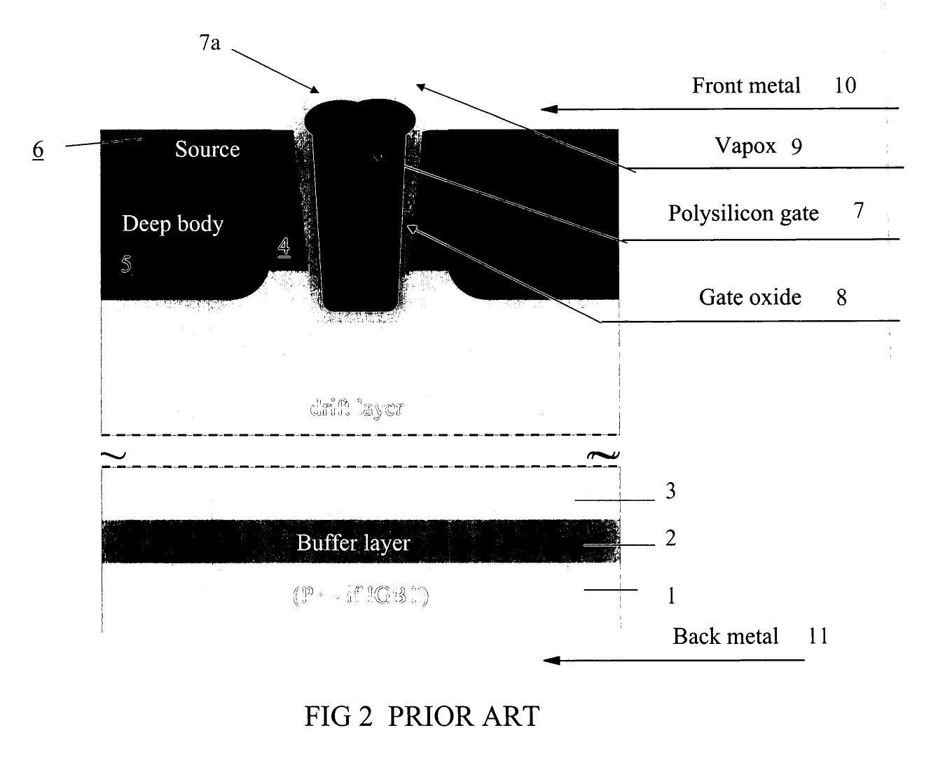

FIG. 3 schematically shows a second alternative of the device of FIG. 1;

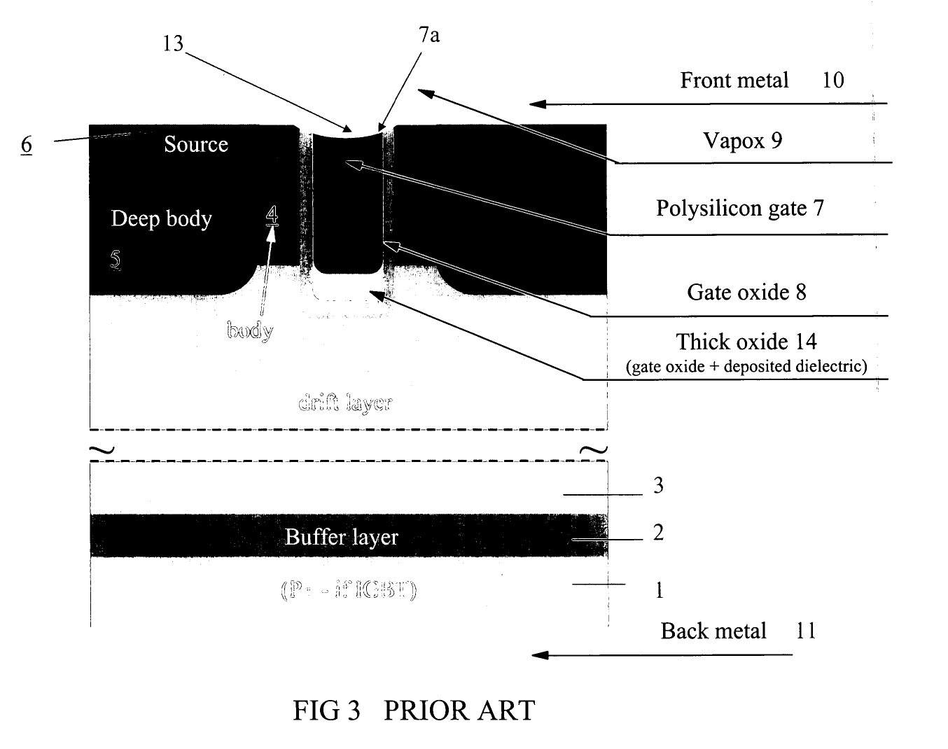

FIG. 4 is a cross-sectional schematic view of a power device according to an embodiment of the present invention;

FIG. 5 is a cross-sectional schematic view of a process step according to a first alternative embodiment of the device of FIG. 4;

FIG. 6 is a cross-sectional schematic view of a process step according to a second alternative embodiment of the device of FIG. 4; and

FIG. 7 is a cross-sectional schematic view of an alternative embodiment of the power device realised according to the invention.

### DETAILED DESCRIPTION

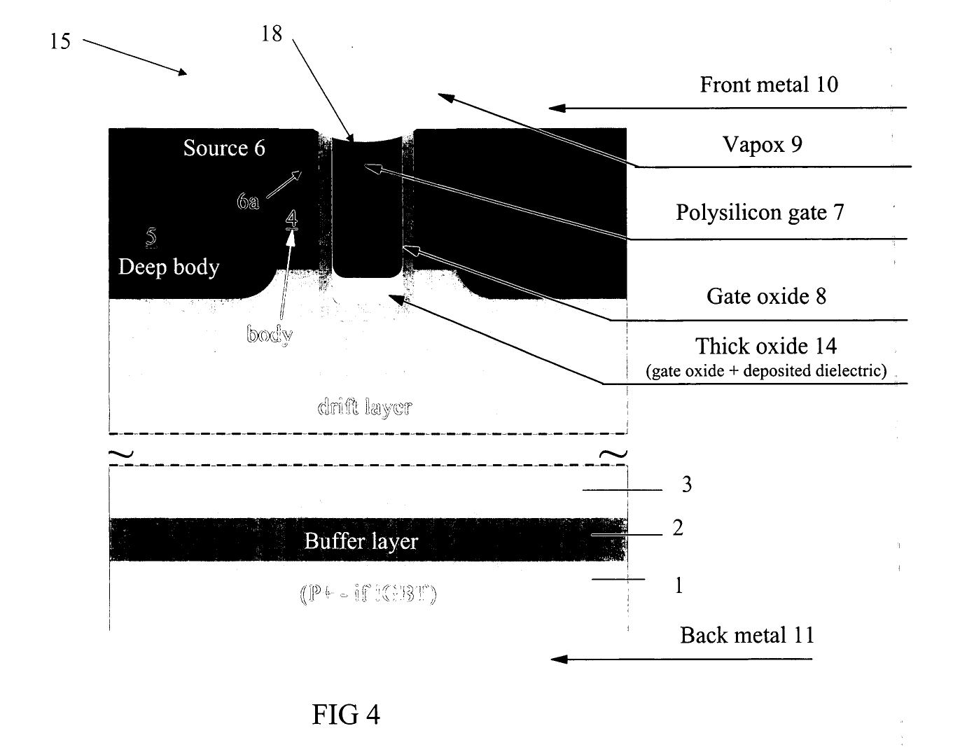

With reference now to FIGS. 4-7, a method is described for manufacturing an insulated trench-gate MOS power device 15 having controlled channel length and a corresponding MOS power device 15.

With particular reference to the example of FIG. 4, the sequence of steps of the method according to the invention leading to the formation of a power device 15 of the above-mentioned type is shown hereafter.

The method steps and the structures according to an embodiment of the present invention can be implemented together with the integrated circuit manufacturing techniques presently used in this field.

The figures representing cross sections of a semiconductor device during the manufacturing are not drawn to scale, but they are instead drawn in order to show the important features of the invention.

For convenience of illustration, elements being structurally and functionally identical with respect to the prior art will be given the same numeral references.

The method according to an embodiment of the present invention thus includes the following steps:
providing a starting semiconductor substrate 1 (of a first conductivity type, particularly of the N+ type for a MOS power transistor or of a second conductivity type, particularly of the P+ type for an IGBT device);
epitaxial growth of a layer of the N-type (drift layer) 3 with possible preventive growth of a buffer layer of the N+ type 2 at the interface with the semiconductor substrate 1;
forming edge structures of the power device 15 with a field oxide layer;
exposure of the active area of the device 15 by removing the field oxide layer;
forming a body region 4 on the semiconductor substrate 1, for example by the use of an unmasked P-type implant;
forming a deep body region 5 of the device 15 being adjacent to the body region 4, for example by a P+ type implant with a photoresist mask;
forming a source region 6 on body regions 4, 5, for example by an N+ type implant with a photoresist mask;
alignment of a hard mask 16 for etching the semiconductor substrate 1; and
etching of the semiconductor substrate 1 to form a trenchgate structure 18 by forming a trench 17 having, in a lower or bottom portion of the trench 17, a U-profile, for example through anisotropic dry etching.

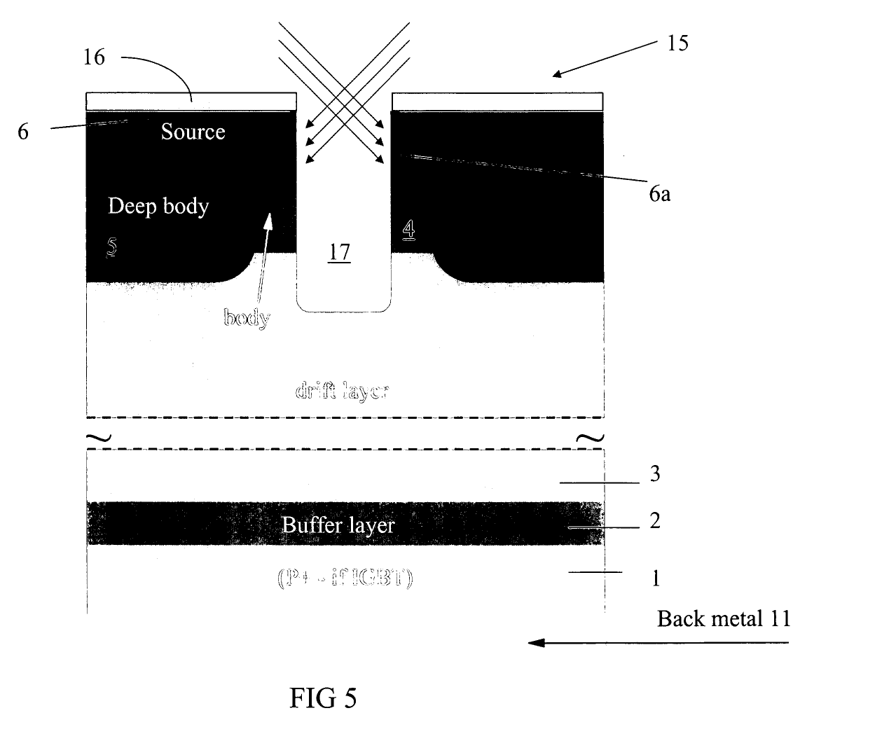

The method of the present invention includes a further step of:
implanting a dopant equal to that implanted to form the source region 6 with such a slope as to partially implant the dopant in the walls of the trench 17 up to a predetermined depth as shown in FIG. 5, thus forming at least a deep source portion 6a on the walls of the trench 17.

The implant is ideally performed on two quadrants (i.e. in two directions having opposite angles with respect to the vertical).

The implant is activated by using one of the following thermal processes. For example, the thermal budget related to the sacrificial oxidation step could be used.

In this way the cleaning of the trench 17 walls and the activation of the dopant forming the source deep portion 6a on the trench 17 walls are provided simultaneously.

The method according to the invention is traditionally carried on with the following steps:
removal of the sacrificial oxide layer from the trench 17 walls;
formation of a coating layer 8 which coats the trench 17, to form a gate dielectric layer, for example through oxidation;
depositing of a conductive layer 7 in the trench 17 to complete the trench-gate structure 18 and thus the gate region of the device 15;
continuation of the manufacturing process to define front metallization contacts 10, final passivation and back metallization 11, similarly to known technologies.

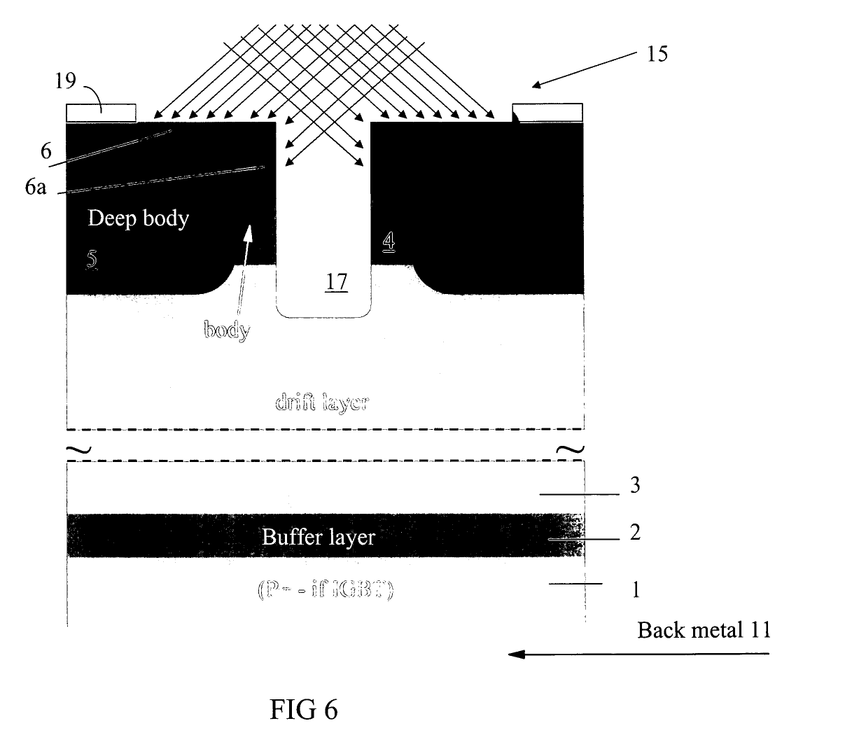

In an alternative embodiment of the method according to the invention, shown in FIG. 6, the manufacturing steps are thus modified after forming the deep body region 5 of the device 15:
formation of a hard mask 16 on the semiconductor device 1;
etching of the semiconductor layer 1 to realise a trench 17 having, in a lower or bottom portion of the trench 17 itself, a U-profile, for example through anisotropic dry etching;
removal of the hard mask 16;
formation of a mask 19, for example resist, on the semiconductor 1;
formation of the source region 6 and of the relevant deep portion 6a through a sloping or angled implant of a doping variety, as shown in FIG. 6. Also in this embodiment the implant is ideally performed on two quadrants; and
diffusion of the source region 6 and of the deep portion 6a for example through an oxidation step; the possible so-grown oxide layer also serves as sacrificial oxide for the walls of the trench 17.

The process according to an embodiment of the present invention is carried on as the above-described process starting from the sacrificial oxide removal.

A power device 15 with insulated gate having a trench-gate structure 18 is thus provided on a P+ semiconductor material substrate 1 whereon an epitaxial semiconductor layer split into buffer layer 2 and drift layer 3, of the N+ and N-type respectively, is grown. Two differently-doped P regions are formed on the layer 3: a body region 4 developing along a trench 17 and a deep body region 5 being adjacent thereof, generally deeper than the body region 4. A source N region 6 is realised on body regions 4, 5.

The device 15 comprises a trench-gate structure 18 forming the device gate region, the trench-gate structure 18 being provided by a trench 17 made in the semiconductor substrate 1 filled in with a polysilicon layer 7. The trench-gate structure 18 is separated from the other portions of the integrated structure by means of a silicon oxide coating layer 8 grown on the walls of the trench 17.

According to the invention, the source region 6 formed on the semiconductor substrate 1 includes a deep source portion 6a extending along the walls of the trench 17 for a predetermined length.

A dielectric layer 9, a metal contact 10 on the semiconductor substrate 1 front and a metal contact 11 on the semiconductor substrate back traditionally complete the device 15.

As already mentioned, it is important to note that the solution according to an embodiment of the present invention allows the device channel length to be adjusted almost independently from overall thermal budgets. For example, if a source region 6 is formed by an arsenic implant, the subsequent source junction depth is very small, even with a considerable thermal budget. This problem is more and more emphasized when a recessed polysilicon structure is used, since a polysilicon layer is lower than the edge on the device top, but simultaneously higher than the source-body junction.

This makes the etching step of the recessed polysilicon critical.

On the contrary, forming the implant on the side walls of the trench 17 to form the deep portion 6a allows an overall source region 6, 6a with the desired depth to be obtained, only linked to geometric factors.

This feature of the method and device according to the invention is very important since, besides removing some criticalities in the process, it also helps to improve the device electric features. In fact, when calculating the conduction losses of a power device, once the J-FET component is eliminated by the trench-gate structure, the main component is the one linked to the channel. This component is particularly important for devices belonging to a voltage class being lower than 50 V. The solution according to an embodiment of the invention, by forming a short channel, allows the conduction loss component to be reduced to a minimum.

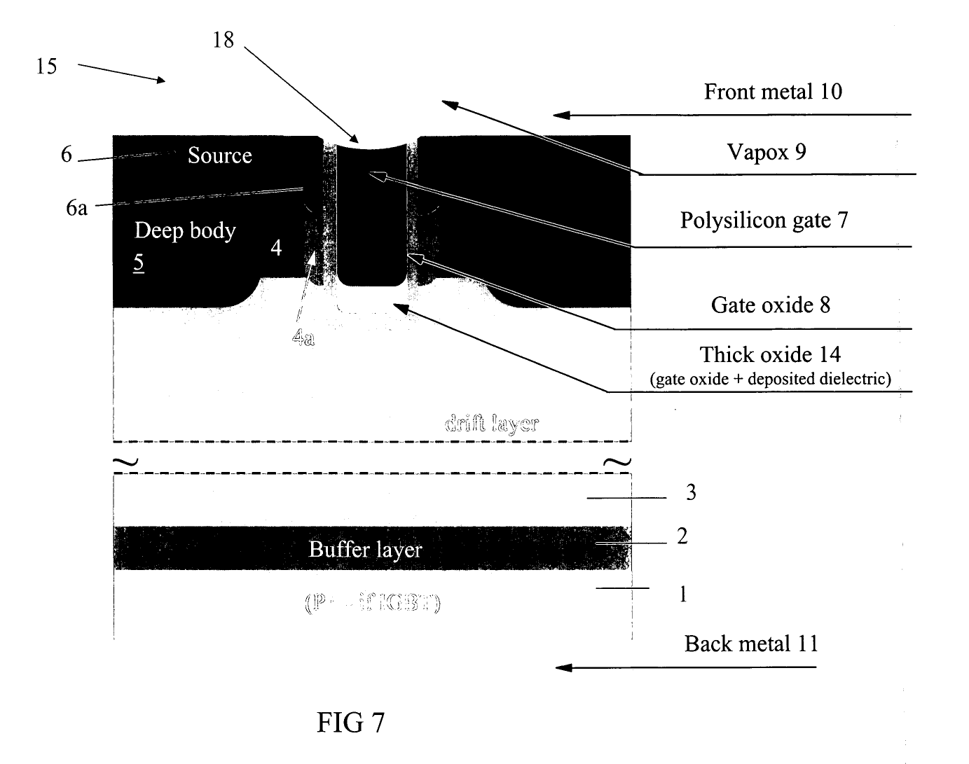

An alternative embodiment of the method according to the invention is now described, including adding a sloping or angled implant to optimize the body region 4, whose final structure is shown in FIG. 7.

A deep portion 4a of the body region 4 is thus formed, being adjacent to the body region 4 on the walls of the trench 17 and extending up to a predetermined depth being higher than the source region 6 portion.

Ideally, this implant is performed simultaneously with the sloping implant to realise the deep source portion 6a (just before or just after). In this alternative embodiment, the implant for forming the body region 4 is used to ensure the electric continuity between the channel region and the deep body region 5, while the sloping implant is used to complete the channel region, making the dopant concentration uniform and adjusting the device threshold voltage.

An alternative embodiment of the device 15 according to the invention is thus obtained, wherein the body region 4 formed on the semiconductor substrate 1 ideally includes a deep body portion 4a formed along said trench 17.

In particular, the deep body portion 4a formed on the semiconductor substrate 1 is deeper than the deep source portion 6a realised along the trench 17.

This is a very important result. In fact, in a MOS power device 15, having a variable concentration of the semiconductor substrate 1 along the channel involves short channel or punch-through effects.

According to the invention, by extending the body region 4, 4a along the walls of the trench 17, the dopant concentration, for example boron, in the channel region is contained at a very reduced distance from the interface. Therefore, the channel region is not determined by a diffusion profile, with a high concentration gradient, as it happens instead in traditional devices, but it is mainly determined by the implant and thus with a box concentration profile. This reduces the possible above-mentioned undesired effects.

In this alternative embodiment, as previously mentioned, the active portion of the body region 4 coincides with the deep portion 4a formed by the sloping dopant implant, while the surface-implanted body region 4 simply serves to ensure the electric continuity between the deep body region 5 and the channel region.

By virtue of this fact, the dedicated implant for realising the surface-realised body region 4 can be removed and the electric continuity between the deep body region 5 and the channel region can be ensured by an already available dopant implant in the normal process flow for forming the device 15 according to the invention, provided that it is of the same variety and with a lower concentration, such as for example the implant used for providing the ring region.

The method according to the invention can be implemented on any prior art structure in the field of trench-gate power devices with insulated gate.

In conclusion, the method and device according to the invention allow:
determination of the channel length independently from the thermal budget and the variety of dopant used for forming the source region;
reduction of the predetermined channel resistance almost independently from the process being used; and
when using a trench-gate structure 18 with a polysilicon layer being recessed in the trench 17, independence between the thermal processes used to form the source and the other structures and the etching process used to recess the polysilicon.

While there have been described above the principles of the present invention in conjunction with specific components, circuitry and bias techniques, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The applicants hereby reserve the right to formulate new claims to such features and/or combinations of such features during the prosecution of the present application or of any further application derived therefrom.

1. A method for manufacturing an insulated trench-gate power device integrated on a semiconductor substrate, comprising:
providing a body region in said semiconductor substrate;
forming a surface source region on said body region;
etching the semiconductor substrate;
forming a trench to form the trench-gate structure; and
forming a deep portion of the source region along the trench.

2. The method of claim 1, wherein the surface source region is formed on the semiconductor substrate around the trench simultaneously with the deep source portion.

3. The method of claim 1 further comprising forming a deep body portion extending to a predetermined depth beyond the depth of the deep source portion.

4. The method of claim 1 wherein the deep source portion is formed using a sloping implant.

5. The method of claim 3, wherein the deep body portion is formed using a sloping implant.

6. The method of claim 4 wherein the sloping implant is formed on two quadrants.

7. The method of claim 5 wherein the sloping implant is formed on two quadrants.

8. An insulated trench-gate power device comprising:
a semiconductor substrate;
a body region in the semiconductor substrate;
a surface source region on the body region;
a trench-gate structure for forming a gate region of the device including a trench made in the semiconductor substrate; and
wherein the surface source region includes a deep source portion along the trench.

9. The device of claim 8, wherein the body region comprises a deep body portion along the trench.

10. The device of claim 9, wherein the deep body portion extends to a predetermined depth beyond the depth of the deep source portion.

11. An insulated trench-gate device comprising:
an insulated trench;
a source region adjacent to the insulated trench; and
a deep source region along the insulated trench, wherein the channel length of the device is determined independently from the thermal budget of the device.

12. The insulated trench gate device of claim 11 wherein the channel length of the device is also determined independently from the dopant used for forming the source region.

13. The insulated trench gate device of claim 11 wherein the insulated trench comprises a trench having a U-shaped profile.

14. The insulated trench gate device of claim 11 wherein the insulated trench further comprises a recessed polysilicon portion.

15. The insulated trench gate device of claim 14 wherein the thermal processes used to form the source and the etching process used to recess the polysilicon portion are independent.

16. The insulated trench gate device of claim 11 wherein the trench further comprises a thick oxide portion.

17. The insulated trench gate device of claim 11 further comprising a deep body portion.

18. The insulated trench gate device of claim 17 wherein the depth of the deep body portion extends below the depth of the deep source region.

19. The insulated trench gate device of claim 11 further comprising a body region.

20. The insulated trench gate device of claim 11 wherein the trench further comprises a recessed portion.
